(19) United States
(12) Patent Application Publication
(10) Pub. No.: US 2006/0237517 A1
(43) Pub. Date: Oct. 26, 2006

(54) Apparatus and manufacturing method of combining low melting point alloys and application of low melting point alloys

(76) Inventor: Tzung-Lung Lee, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/113,012

(22) Filed: Apr. 25, 2005

(51) Int. Cl. H01L 29/06; B23K 31/02

(52) U.S. Cl. 228/256; 257/33

(57) ABSTRACT

An apparatus and a manufacturing method of combining low melting point alloys and an application of low melting point alloys use a low melting point alloy (solder) as a heat-conducting medium. The solder is attached on the surface of a heat sink to define a heat-dissipating device installable onto a heat source (chip) for facilitating heat dissipations. The coefficient of thermal conduction of the solder is high, so that the heat produced by the chip can be conducted to the heat sink to give better heat dissipations of the chip. The characteristic of the low melting point alloy is used to enhance the thermal conduction for the heat source of the chip.

### BACKGROUND OF THE INVENTION

1. Field of the Invention

The present invention relates to an apparatus and a manufacturing method of combining low melting point alloys and application of low melting point alloys, and more particularly to an apparatus, a manufacturing method and an application for a heat-dissipating device for facilitating heat dissipation.

2. Description of Related Art

Reference is made to FIG. 1 for a prior art heat-dissipating device used for semiconductor chip packages. The heat-dissipating device comprises a substrate 8 and a heat sink 9. The substrate 8 includes a chip 81 installed thereon, and the heat sink 9 is made of a good thermal conductive metal. The heat sink 9 covers the chip 81 of the substrate 8 and has a periphery 91, and the periphery 91 is adhered onto the substrate 8 by glue.

To insure that the heat produced by the chip 81 is conducted to the heat sink 9, a thermally conductive grease 7 is usually applied between the chip 81 and the heat sink 9. The heat sink 9 is attached onto the chip 81 through the thermally conductive grease 7, so that the heat of the chip 81 is conducted to the outside by the thermally conductive grease 7 and the heat sink 9 for facilitating the heat dissipation of the chip 81 and protecting the chip 81 from being damaged by external forces.

Since the foregoing heat-dissipating device uses the thermally conductive grease 7 as a heat-conducting medium, it is difficult to conduct the heat produced by the chip 81 to the heat sink 9 because the coefficient of thermal conductivity (TC) of the thermally conductive grease 7 is very low (approximately 2-3). As a result, such heat-dissipating device has a poor heat dissipating performance.

### SUMMARY OF THE INVENTION

Therefore, it is a primary objective of the present invention to make use of the high thermal conductivity and thermal stress free characteristics of a low melting point alloy to improve the heat dissipating performance of a chip and provide an apparatus and a manufacturing method of combining low melting point alloys. The invention uses a low melting point alloy (solder) as a heat-conducting medium to prevent the production of air bubbles (vias), and the coefficient of thermal conductivity is high, so that the heat produced by a chip can be conducted effectively to the heat sink to give a better heat dissipating performance.

To achieve the foregoing objective, the apparatus for combining low melting point alloys comprises a heat sink, having at least one surface, and at least one solder, made of a low melting point alloy and attached on a surface of the heat sink.

The present invention further provides a manufacturing method of combining a low melting point alloy that comprises the following steps. A heat sink is formed. A tool is used to attach at least one solder onto a surface of the heat sink. The heat sink is sent into a reflow furnace, so that the solder is soldered onto a surface of the heat sink. The heat sink and solder are integrally fixed after being cooled to room temperature.

The present invention further provides an application of combining a low melting point alloy that applies a low melting point alloy as a thermal conductive interface material.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a cross-sectional view of a prior art heat-dissipating device;

FIG. 2 is a cross-sectional view of an apparatus of the present invention;

FIG. 3 is a cross-sectional view of an apparatus according to another preferred embodiment of the present invention;

FIG. 4 is a cross-sectional view of an application of an apparatus of the present invention;

FIG. 5 is a flow chart of a manufacturing method of the present invention; and

FIG. 6 is a schematic view of using a tool according to the manufacturing method of the present invention.

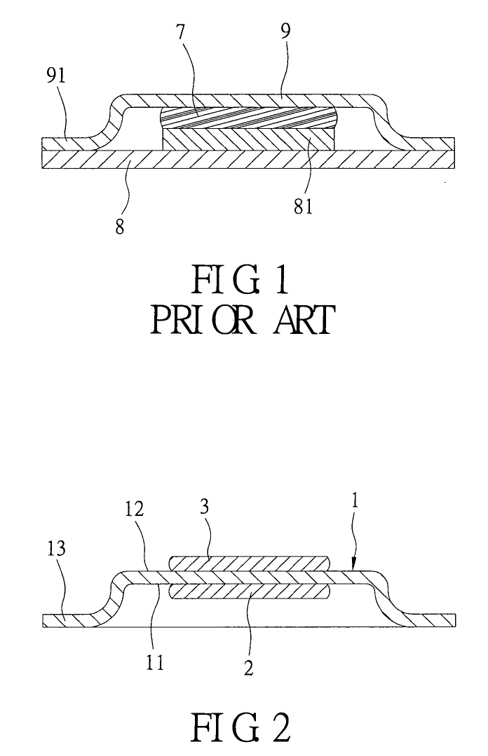

### DETAILED DESCRIPTION OF THE PREFERRED EMBODIMENTS

The above and other objects, features and advantages of the present invention will become apparent from the following detailed description taken with the accompanying drawings. However, the drawings are provided for reference and illustration, but not intended to limit the present invention.

Reference is made to FIG. 2 for an apparatus for combining low melting point alloys. In this preferred embodiment, the apparatus is a heat-dissipating device comprising a heat sink 1, a first solder 2 and a second solder 3. The heat sink 1 is made of a good thermally conductive metal and includes a first surface 11 and a second surface 12. The first surface 11 and second surface 12 are disposed on the bottom surface and the top surface of the heat sink 1, respectively. The external edge of the heat sink 1 is extended downward to form a periphery 13. After the heat sink 1 is formed, the first surface 11 and second surface 12 are electroplated with a nickel material, so that the first solder 2 and second solder 3 can be attached onto the heat sink 1 more easily.

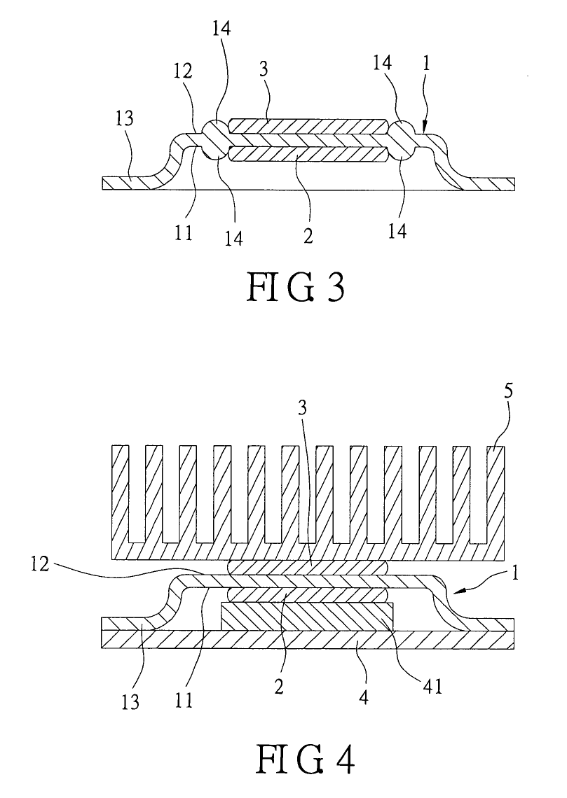

The first solder 2 and second solder 3 are made of low melting point alloys and attached onto the first surface 11 and second surface 12 of the heat sink 1, respectively, by a tool, so that the tool controls the size of the first solder 2 and second solder 3 to prevent the solders 2, 3 from expanding. Further, a margin 14 is disposed separately on the first surface 11 and second surface 12 of the heat sink 1, as shown FIG. 3. The margin 14 is disposed around the external periphery of the solders 2, 3 to prevent the solders 2, 3 from flowing out.

If the apparatus is sent into a reflow furnace, the first solder 2 and second solder 3 will be soldered onto the first surface 1 1 and second surface 12 of the heat sink 1, respectively. The heat sink 1, first solder 2 and second solder 2 will be fixed integrally after being cooled to room temperature. With the foregoing assemblies, the heat-dissipating device for combining low melting point alloys is defined.

Reference is made to FIG. 4 for the heat-dissipating device. The heat sink 1 covers a chip 41 of a substrate 4. The periphery 13 of the heat sink 1 is glued onto the substrate 4, and the first solder 2 is disposed on the chip 41, so that the first solder 2 is disposed between the chip 41 and the heat sink 1. Further, the second solder 3 includes a heat-dissipating device 5 installed thereon, so that the second solder 3 is disposed between the heat-dissipating device 5 and the heat sink 1. If the device is sent into a reflow furnace, the first solder 2 will be soldered between the chip 41 and the first surface 11 of the heat sink 1, and the second solder 3 will be soldered between the heat-dissipating device 5 and the second surface 12 of the heat sink 1. The heat sink 1, first solder 2, second solder 3, chip 41 and heat-dissipating device are fixed integrally after being cooled to room temperature.

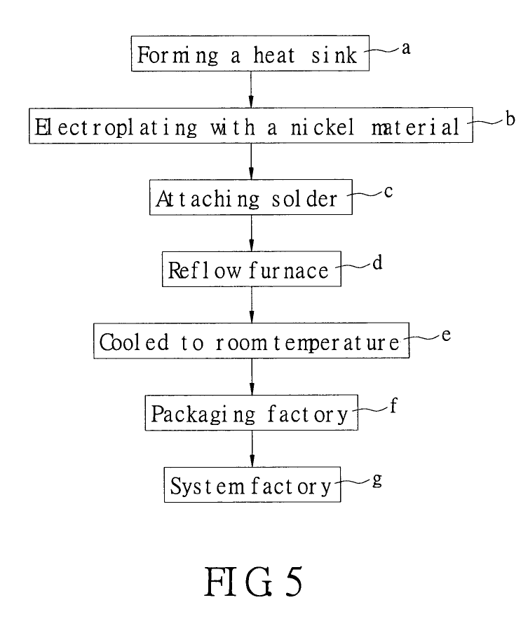

Reference is made to FIG. 5 together with FIGS. 2 and 4 for a manufacturing method of combining low melting point alloys, and the method relates to a heat-dissipating device manufacturing method, comprising the following steps:

(a) A heat sink 1 is formed.

(b) A nickel material is electroplated onto a surface of the heat sink 1.

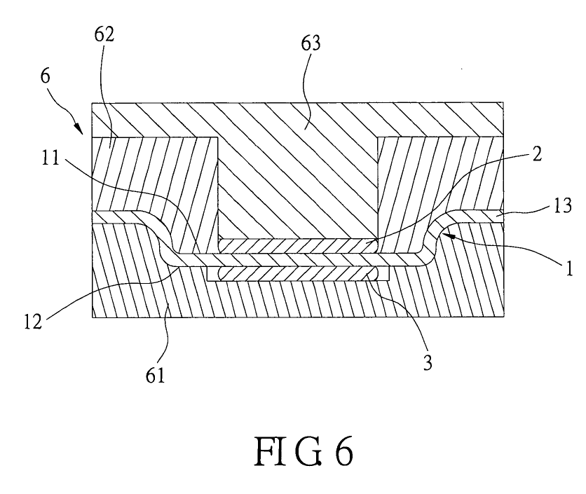

(c) A tool 6 is used to attach a first solder 2 and a second solder 3 onto a first surface 11 and a second surface 12, respectively, to fix the heat sink 1 as shown in FIG. 6, and thus the tool 6 precisely controls the dimensions (length, width and thickness) of the first solder 2 and second solder 3 to prevent the solders 2, 3 from expanding. The tool 6 is comprised of a lower mold 61, a middle mold 62 and an upper mold 63. The lower mold 61 and middle mold 62 include an appropriate mold cavity for accommodating the solders 2, 3, and the solders 2, 3 for the lower mold 61, middle mold 62 and upper mold 83 are made of a material not adhesive to aluminum materials so as to prevent the solders 2, 3 from adhering onto the tool 6;

(d) The molds are sent into the reflow furnace, so that the first solder 2 and second solder 3 are soldered to the first surface 11 and second surface 12 of the heat sink 1, respectively.

(e) The heat sink 1, first solder 2 and the second solder are fixed integrally.

(f) The chip 41 is sent to a packaging factory for its packaging, such that the heat sink 1 of the heat-dissipating device covers the chip 41 of the substrate 4, the periphery 13 of the heat sink 1 is glued onto the substrate 4, the first solder 2 is disposed on the chip 41, and the first solder 2 is disposed between the chip 41 and the heat sink 1. If the device is sent into the reflow furnace, the first solder 2 will be soldered between the first surface 11 of the heat sink 1 and the chip 41. The heat sink 1, the first solder 2 and the chip 41 are fixed integrally after being cooled to room temperature.

(g) The heat-dissipating device 5 is sent to a system factory for assembly, and the heat-dissipating device 5 is installed on the second solder 3, such that the second solder 3 is disposed between the heat-dissipating device 5 and the heat sink 1. The device is sent into a reflow furnace (or heated by a heat gun according to the properties of the solder and the operation of the heating device) to solder the second solder 3 between the heat-dissipating device 5 and the second surface 12 of the heat sink 1. The heat sink 1, the second solder 3 and the heat-dissipating device 5 are fixed integrally after being cooled to room temperature.

The present invention provides an application of a low melting point alloy that uses a low melting point alloy as the thermally conductive interface material.

The present invention uses low melting point alloys (solders 2, 3) as the thermal conductive media, and the coefficient of thermal conductivity of the solders 2, 3 is high (up to 10-50), so that the heat produced by the chip 41 can be conducted effectively to the heat sink 1 and the heat-dissipating device 5 to give a better heat dissipation performance.

Further, the present invention uses low melting point alloys for the solders 2, 3 to prevent any production of air bubbles (vias). Air bubbles (or vias) are a major drawback of using general solder pastes or solder bar for the soldering, and it also requires a solder flux. If a low melting point alloy is a pure metal alloy without any organic matter, then there will be no air bubble or via produced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An apparatus for combining low melting point alloys, comprising:
a heat sink, having at least a surface; and
a solder, made of a low melting point alloy and attached onto said surface of said heat sink.

2. The apparatus for combining low melting point alloys of claim 1, wherein said surface of said heat sink is a first surface, and said solder is a first solder, and said first solder is attached onto said first surface of said heat sink.

3. The apparatus for combining low melting point alloys of claim 2, wherein said heat sink covers said chip of a substrate, said first solder is disposed between said chip and said heat sink, and said first solder is soldered between said chip and said first surface of said heat sink,

4. The apparatus for combining low melting point alloys of claim 1, wherein said surface of said heat sink includes a first surface and a second surface, said solder includes a first solder and a second solder, and said first solder and second solders are attached to said first and second surfaces of said heat sink, respectively.

5. The apparatus for combining low melting point alloys of claim 4, wherein said heat sink covers a chip of a substrate, and said first solder is disposed between said chip and said heat sink, said first solder is soldered between said chip and said first surface of said heat sink, said second solder installs a heat-dissipating device thereon, said second solder is disposed between said heating dissipating device and said heat sink, and said second solder is soldered between said heat-dissipating device and said second surface of said heat sink.

6. The apparatus for combining low melting point alloys of claim 1, wherein the at least a surface of said heat sink is electroplated with a nickel material.

7. The apparatus for combining low melting point alloys of claim 1, wherein said heat sink has a margin disposed on the at least a surface, and said margin is disposed around an external periphery of said solder.

8. A manufacturing method of combining low melting point alloys, comprising the steps of:
forming a heat sink;
using a tool to attach at least one solder onto a surface of said heat sink;
sending said heat sink into a reflow furnace, wherein said solder is soldered onto the surface of said heat sink; and
cooling said heat sink to room temperature, wherein said heat sink and said solder are integrally fixed.

9. The manufacturing method of combining low melting point alloys of claim 8, wherein the surface of said heat sink is electroplated with a nickel material.

10. The manufacturing method of combining low melting point alloys of claim 8, wherein said tool is made of a material not adhesive to said solder.

11. The manufacturing method of combining low melting point alloys of claim 8, further comprising the steps of covering a chip of a substrate with said heat sink, wherein said solder is disposed between said chip and said heat sink, and said solder is soldered between a surface of said heat sink and said chip, and cooling said heat sink, said solder and said chip to room temperature, wherein said heat sink, said solder and said chip are integrally fixed.

12. The manufacturing method of combining low melting point alloys of claim 8, further comprising a heat-dissipating device, wherein said solder is disposed between said heat-dissipating device and said heat sink, said solder is soldered between said heat-dissipating device and the surface of said heat sink, and said heat sink, said solder and said heat-dissipating device are integrally fixed after being cooled to room temperature.

13. A manufacturing method of combining low melting point alloys, comprising the steps of:
forming a heat sink;
using a tool to attach at least one solder onto a surface of said heat sink; and
integrally fixing said heat sink and said solder by cooling to room temperature.

14. An application of low melting point alloys, comprising an application of a low melting point alloy as a thermally conductive interface material.
